(19) United States
(12) Patent Application Publication
(10) Pub. No.: US 2013/0081690 A1
(43) Pub. Date: Apr. 4, 2013

(54) Spectral Modification

(71) Applicants: Charles M. Fortmann, Bellport, NY (US); Eric David Laufer, New York, NY (US)

(72) Inventors: Charles M. Fortmann, Bellport, NY (US); Eric David Laufer, New York, NY (US)

(21) Appl. No.: 13/457,254

(22) Filed: Apr. 26, 2012

Related U.S. Application Data
(63) Continuation-in-part of application No. 13/455,993, filed on Jul. 10, 2012.
Application No. 13/455,993 is a continuation-in-part of application No. 12/175,208, filed on Jul. 17, 2008.
(60) Provisional application No. 60/950,234, filed on Jul. 17, 2007.
(60) Provisional application No. 61/081,492, filed on Jul. 17, 2008.
(60) Provisional application No. 61/081,494, filed on Jul. 17, 2008.
(60) Provisional application No. 61/478,601, filed on Apr. 25, 2011.
(60) Provisional application No. 61/576,753, filed on Dec. 16, 2011.

(51) Int. Cl. H01L 31/0232; H01L 31/18; G02B 5/02

(52) U.S. Cl. CPC H01L 31/02327; G02B 5/02; H01L 31/18
USPC 136/256; 359/599; 427/162; 438/69

(57) ABSTRACT

Spectral modification devices and methods are described. For example, an apparatus for spectral modification of incident radiation includes a substrate and Raman shifting material embedded in or on the substrate, the Raman shifting material selected based on a desired optical or electrical performance of a light absorbing structure.

### CROSS-REFERENCE TO RELATED APPLICATIONS

This application is a continuation-in-part of, claims the benefit of, and priority to U.S. application Ser. No. 13/455,993, filed Apr. 25, 2012 and titled “Spectral Modification,” which is a continuation-in-part of, claims the benefit of, and priority to U.S. application Ser. No. 12/175,208, filed Jul. 17, 2008 and titled “Solar Cell,” which claims the benefit of U.S. Provisional Application No. 60/950,234, filed Jul. 17, 2007, U.S. Provisional Application No. 61/081,492, filed Jul. 17, 2008, and U.S. Provisional Application No. 61/081,494, filed Jul. 17, 2008, the entire contents of each of which are incorporated herein by reference.

U.S. application Ser. No. 13/455,993, filed Apr. 25, 2012 and titled “Spectral Modification,” claims the benefit of U.S. Patent Application No. 61/478,601, filed Apr. 25, 2011 and titled “Spectral Modification” and U.S. Patent Application No. 61/576,753, filed Dec. 16, 2011 and titled “Spectral Modification,” the entire contents of each of which are incorporated herein by reference.

The contents of U.S. patent application Ser. No. 12/701,272, filed Feb. 5, 2010 and titled “Energy Conversion Cell Having a Dielectrically Graded Region to Alter Transport, and Methods Thereof,” and U.S. patent application Ser. No. 12/915,958, filed Oct. 29, 2010 and titled “Light Scattering and Transport for Photosensitive Devices” are hereby incorporated by reference.

### TECHNICAL FIELD

The description relates to spectral modification, scattering, and diffusion of light.

### BACKGROUND

The technology arises, in part, from the desire to increase the efficiency of solar cells. Over thirty years of solar cell advancement provides a vista to new strategic technologies for greater solar energy production. Some commercial solar cells can achieve nearly 100% internal quantum efficiency (e.g., efficiency of transforming solar radiation into electricity) over a portion of the solar spectrum, while having low quantum efficiency over other portions of the solar spectrum. Accordingly, there is a need to improve solar cell efficiency for incident light in the portions of the solar spectrum for which solar cells have low quantum efficiency.

### SUMMARY

Spectral modification can improve solar cell performance by converting radiation in the portions of the solar spectrum for which the solar cell has low quantum efficiency to radiation of wavelengths that can be efficiently absorbed by the solar cell.

In general, the technology relates to an apparatus for spectral modification of incident radiation. The apparatus includes a substrate and Raman shifting material embedded in or on the substrate, the Raman shifting material selected based on a desired optical or electrical performance of a light absorbing structure.

In some embodiments, the Raman shifting material includes nano-scale particles and powdered materials. In some embodiments, the powdered materials include diamond powder. In some embodiments, the nano-scale particles include silver, aluminum, aluminum alloy, or any combination thereof. In some embodiments, the Raman shifting material includes titanium oxide, diamond, or any combination thereof. In some embodiments, the apparatus includes reflective material embedded in or on the substrate. In some embodiments, the apparatus includes silicon dopants embedded in or on the substrate.

In some embodiments, the Raman shifting material includes one or more composite particles, with each composite particle including: a first particle, wherein the first particle includes one of scattering material, Raman shifting material, or reflective material; and a first material disposed against at least a portion of the first particle, wherein the first material includes one of scattering material, Raman shifting material, or reflective material, further wherein the first particle and the first material include different materials.

In another aspect, the technology relates to an apparatus including a solar cell, a spectral modification layer disposed against at least a portion of the solar cell, the spectral modification layer comprising a Raman shifting material selected based on a desired optical or electrical performance of the solar cell.

In some embodiments, the Raman shifting material includes nano-scale particles and powdered materials. In some embodiments, the powdered materials include diamond powder. In some embodiments, the nano-scale particles include silver, aluminum, aluminum alloy, or any combination thereof. In some embodiments, the Raman shifting material includes titanium oxide, diamond, or any combination thereof. In some embodiments, the apparatus includes reflective material embedded in or on the substrate. In some embodiments, the apparatus includes silicon dopants embedded in or on the substrate. In some embodiments, the solar cell is a silicon solar cell or dye-type solar cell.

In some embodiments, the Raman shifting material includes one or more composite particles, with each composite particle including: a first particle, wherein the first particle includes one of scattering material, Raman shifting material, or reflective material; and a first material disposed against at least a portion of the first particle, wherein the first material includes one of scattering material, Raman shifting material, or reflective material, further wherein the first particle and the first material include different materials.

In another aspect, the technology relates to a method of manufacturing a spectral modification material. The method includes forming a substrate and embedding in or on the substrate a Raman shifting material, the Raman shifting material selected based on a desired optical or electrical performance of a light absorbing structure.

In another aspect, the technology relates to a method of reducing series resistance of a solar cell. The method includes selecting a Raman shifting material based on a desired optical performance of the solar cell. The method includes selecting a conductive material based on a desired electrical performance of the solar cell, wherein the conductive material is at least partially reflective. The method includes disposing a spectral modification layer in optical communication with a portion of the solar cell, the spectral modification layer comprising the Raman shifting material and the conductive material.

In another aspect, the technology relates to a method of reducing series resistance between two or more solar cells. The method includes selecting a Raman shifting material based on a desired optical performance of the two or more solar cells. The method includes selecting a conductive material based on a desired electrical performance of the two or more solar cells, wherein the conductive material is at least partially reflective. The method includes disposing a spectral modification layer in optical and electrical communication with a portion of each of the two or more solar cells, the spectral modification layer comprising the Raman shifting material and the conductive material.

In another aspect, the technology relates to a composite particle. The composite particle includes a first particle, wherein the first particle includes one of scattering material, Raman shifting material, or reflective material. The composite particle includes a first material disposed against at least a portion of the first particle, wherein the first material includes one of scattering material, Raman shifting material, or reflective material, further wherein the first particle and the first material include different materials.

In some embodiments, the composite particle of claim 21 includes a second material disposed against at least a portion of the first particle, wherein the second material includes one of scattering material, Raman shifting material, or reflective material, further wherein the first particle, the first material, and the second material include different materials.

In some embodiments the Raman shifting material includes diamond. In some embodiments the scattering material includes titanium oxide. In some embodiments, the reflective material includes silver, aluminum, aluminum alloy, or any combination thereof. In some embodiments, the dopant material disposed against the first particle.

### BRIEF DESCRIPTION OF THE DRAWINGS

FIG. 1 depicts a cross-sectional view of a structure or device that includes a solar cell and a spectral modification layer.

FIG. 2 depicts a cross-sectional view of a structure or device that includes a solar cell and a spectral modification layer.

FIG. 3 depicts a cross-sectional view of a structure or device that includes a transparent layer, a solar cell, and a spectral modification layer.

FIG. 4 depicts a cross-sectional view of a structure or device that includes a solar cell and spectral modification layers.

FIG. 5A depicts a composite particle.

FIG. 5B depicts a composite particle.

FIG. 6 depicts an arrangement of composite particles.

FIG. 7 depicts a composite spectral modification layer.

FIG. 8 depicts the Raman spectra of crystalline and nanoscale particle silicon.

FIG. 9 depicts a comparison of a commercial solar cell with the as-delivered rear contact and a solar cell with a diffuse titanium oxide-based rear reflector.

FIG. 10 depicts the quantum efficiency of standard solar cells.

FIG. 11 depicts the ratio of collected photon current to the incident photon flux as a function of the photon energy based on Raman-induced energy diffusion of light.

### DETAILED DESCRIPTION

The technology, in some aspects, relates to films, devices, and structures that facilitate spectral modification. Some applications of the technology facilitate the Raman shift of light to levels that result in improvement of solar cell performance. Raman-shift-based (e.g., Stokes and anti-Stokes shift) wavelength change is based upon the interaction of an incoming photon with quantized lattice vibrations (phonons) whereby the photon wavelength can be increased or decreased by a corresponding phonon absorption or emission. The photon-phonon energy exchange is governed by energy and momentum conservation. Raman shifting does not rely on electronic transitions and/or photon absorption, such as in luminescence. Beneficially, Raman shifting can be used for spectral modification without minimum photon energies or fluxes. For example, when Raman-shifting materials are positioned at or on the rear of a solar cell, parasitic light absorption can be reduced. As another example, when Raman-shifting materials are positioned at or on the face of a solar cell (e.g., the light incident side) incident light can be converted to wavelengths that the solar cell can convert (or more efficiently convert as compared to the incident light's wavelength) into electrical energy.

Some applications of the technology improve solar cell efficiency by facilitating long travel paths of light within the device layers and/or solar cell. Increasing the travel path length of light within the device layers and/or solar cell can increase the amount of light absorbed and converted to electricity by the solar cell.

The technology includes a spectral modification layer. In some embodiments, the spectral modification layer can be a film. In some embodiments, the spectral modification layer can be an apparatus or a structure. In some embodiments, the spectral modification layer can be a matrix including materials that facilitate light scattering and/or spectral modification.

The spectral modification layer can enhance light scattering and Raman-shifting-based spectral modification for solar cell applications. For example, the spectral modification layer can include a titanium-oxide (TiO₂) based rear diffuse reflector that can increase the long-wavelength response of crystalline solar cells. Particles within the TiO₂ can produce a greater Stokes and anti-Stokes shift when compared to bulk crystal counterparts. The anti-Stokes to Stokes shift ratio in these spectral modification layers can also be increased by increasing probe or bias light intensity. When applied to solar cells, the spectral modification layer can extend the red response of the solar cell (e.g., the conversion of incident red light) and thereby increase the overall solar cell performance.

In some embodiments, the spectral modification layer can include TiO₂, diamond powder, silver powder, or any combination thereof. For example, solar cells can be prepared using various combinations of TiO₂, diamond powder, and silver powder-based layers to diffuse-scatter and Raman-shift light. The layers can be used as combination rear contacts for a solar cell.

In embodiments including diamond (e.g., diamond powders), the diamond can facilitate strong Raman-shifts. The anti-Stokes shift of diamond powder can be stronger than that of bulk diamond, and the anti-Stokes-to-Stokes shift amplitude has been found to increase with increasing Raman probe beam intensity. This direct amplitude-intensity relationship is consistent with the concept that the anti-Stokes shift in small-grained particles employs phonons created by a prior Stokes shift event and that phonon decay in small particles is slower.

Near-index matched rear reflector systems can offer increased electrical current without detrimentally increasing surface area. Rear contact layers of solar cells can have lower series resistance when silver powder is mixed in. One possible explanation for the reduced series resistance is that the silver powders are conductive, and provide a current path. The addition of silver powder does not substantially degrade the performance of the spectral modification layers, suggesting the silver powder is sufficiently reflective so as to provide an additional light scattering mechanism to the mechanisms used by TiO₂ particles and/or diamond powder. For example, the TiO₂ particles and diamond powder can scatter light by refractive-index contrast, while the silver powder can scatter light by irregular-shaped, small particles.

Additional particles and/or additional layers deposited onto any of the described light scattering or Raman shifting particles described herein can increase spectral modification. Additional particles and/or a layer on a particle and/or a partial layer on a particle can be added such that the resulting composite film contains highly transparent and/or highly reflective materials, and the Raman shifting particles can be substantially capable of being illuminated internally.

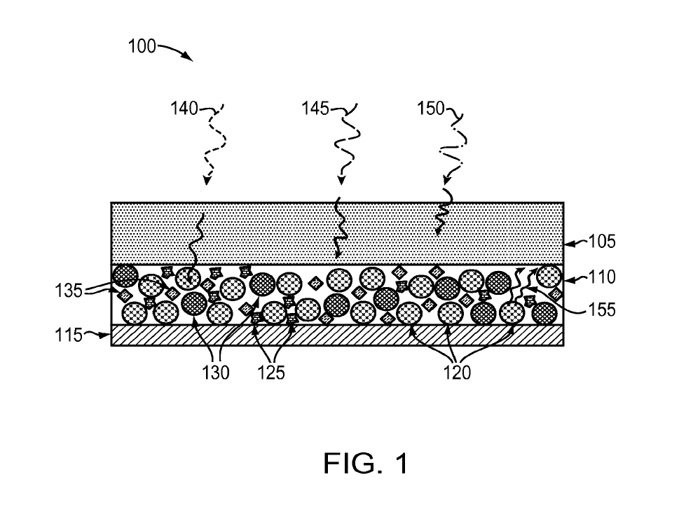

FIG. 1 depicts a cross-sectional view of a structure or device 100 that includes a solar cell 105 and a spectral modification layer 110. In the illustrated embodiment, the spectral modification layer 110 is in optical communication with the back (e.g., not light-incident side) of solar cell 105. Optical communication can be achieved by directly applying spectral modification layer 110 directly to solar cell 105 without having opaque intervening layers (e.g., optically thick metal contacts). Reflective layer 115 is in optical communication with spectral modification layer 110.

Solar cell 105 can be a silicon solar cell (e.g., polycrystalline, amorphous, etc.), photovoltaic cell, dye-type solar cell, CdTe solar cell, or any other kind of solar cell.

Spectral modification layer 110 can include various materials to facilitate spectral modification and/or scattering. In the illustrated embodiment, spectral modification layer 110 includes Raman shifting particles 120, adhesion/cohesion material 125, reflective particles 130, and dopant material 135. Raman shifting particles 120 can include diamond, diamond powders, silicon, and/or TiO₂ particles.

Adhesion/cohesion material 125 can be added to spectral modification layer 110 to facilitate adhesion and/or cohesion of the materials in spectral modification layer 110. Adhesion/cohesion material 125 can be added to spectral modification layer 110 in particle form or film form. The adhesion/cohesion material 125 can be highly reflective or highly transparent. For example, adhesion/cohesion material 125 can include aluminum, silver alloys, various low temperature melting glass, and/or plastics.

Reflective particles 130 can be added to spectral modification layer 110 to enhance scattering and/or electrical conductivity in the spectral modification layer 110. In some embodiments, reflective particles 130 will not substantially reduce the performance (e.g., scattering and/or Raman shifting performance) of the spectral modification layer 110. In some embodiments, reflective particles 130 can be highly reflective metals, such as aluminum, silver, and/or silver alloys. In some embodiments, reflective particles can be coated with well-known reflection enhancing coating to reduce parasitic absorption losses. Such coating can be applied to the outer and/or inner metal surface. Such reflective enhancing films may be prepared using existing technologies such as sputter coating

Dopant material 135 can be added to spectral modification layer 110. Dopant material 135 can be used to dope solar cell 105 by annealing (or heat treatment), where during annealing the dopant material 135 vaporizes and/or diffuses into the material (e.g., silicon, silicon-germanium, and/or cadmium-telluride) of solar cell 105, thereby increasing the conductivity in the near surface regions of solar cell 105 to reduce resistance at electrical contacts. For example, when dopant material 135 includes aluminum particles and is incorporated in spectral modification layer 110, aluminum atoms may penetrate the solar cell 105 during a subsequent anneal at ˜900 C for several seconds.

Reflective layer 115 can be any reflective material. For example, reflective layer 115 can include aluminum, silver, or silver alloys.

While the illustrated embodiment shows structure or device 100 including various components, it should be appreciated that the technology described herein can be implemented with a subset of those components. For example spectral modification layer 110 can include a subset of Raman shifting particles 120, adhesion/cohesion material 125, reflective particles 130, and dopant material 135.

As an example of the operation of structure or device 100, red light 140, green light 145, and blue light 150 can be incident upon structure or device 100. In the illustrated embodiment, red light 140, green light 145, and blue light 150 are incident upon solar cell 105. Green light 145 and blue light 150 are predominately absorbed by solar cell 105. Red light 140 can pass through solar cell 105 and into spectral modification layer 110. Spectral modification layer 110 can scatter and wavelength shift (e.g., Raman shift) red light 140 and emit light 155 at a wavelength solar cell 105 can absorb (e.g., green or blue light). Reflective particles 130 can aid in conduction of electricity produced by solar cell 105 and facilitate longer travel paths for light (e.g., red light 140 and light 155) in and/or passing through spectral modification layer 110 and solar cell 105. It should be appreciated that spectral modification layer 110 can be configured to scatter and/or Raman shift other wavelengths of light depending on its composition and application.

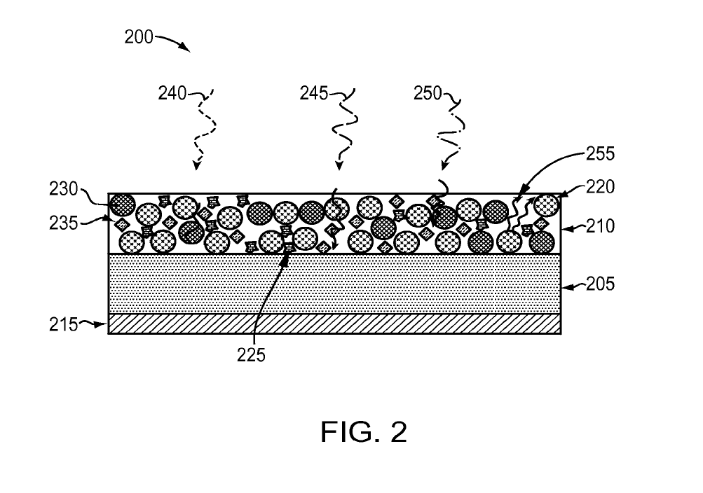

FIG. 2 depicts a cross-sectional view of a structure or device 200 that includes a solar cell 205 and a spectral modification layer 210. In the illustrated embodiment, the spectral modification layer 210 is in optical communication with the light-incident side of solar cell 205. Optical communication can be achieved by directly applying spectral modification layer 210 to solar cell 205 without having opaque intervening layers (e.g., optically thick metal contacts). Reflective layer 215 is in optical communication with the back of solar cell 205.

Spectral modification layer 210 can include various materials to facilitate spectral modification and/or scattering. For example, spectral modification layer 210 can include Raman shifting particles 220, adhesion/cohesion material 225, reflective particles 230, and dopant material 235, as described with respect to FIG. 1.

As an example of the operation of structure or device 200, red light 240, green light 245, and blue light 250 can be incident upon structure or device 200. In the illustrated embodiment, red light 240, green light 245, and blue light 250 are incident upon spectral modification layer 210. Green light 245 and blue light 250 can pass through spectral modification layer 210 and be absorbed by solar cell 205. Spectral modification layer 210 can scatter and wavelength shift (e.g., Raman shift) red light 240 and emit light 255 at a wavelength solar cell 205 can absorb (e.g., green or blue light). It should be appreciated that spectral modification layer 210 can be configured to scatter and/or Raman shift other wavelengths of light depending on its composition and application.

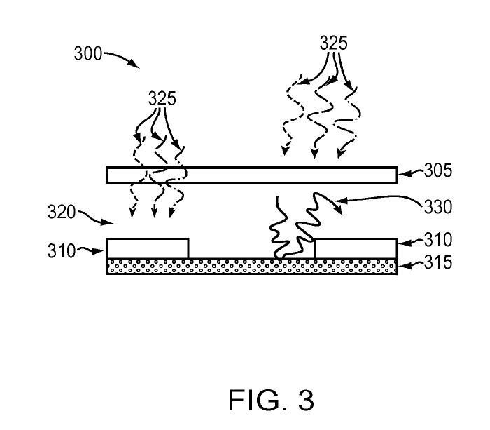

FIG. 3 depicts a cross-sectional view of a structure or device 300 that includes a transparent layer 305, solar cells 310, and a spectral modification layer 315. In the illustrated embodiment, transparent layer 305 is separated from solar cells 310 and spectral modification layer 315 by optical cavity 320. Transparent layer 305 can be in optical communication with solar cells 310 and spectral modification layer 315 via optical cavity 320. Transparent layer 305 can be glass, a flexible material such as plastic, or any other material that is substantially transparent. In the illustrated example, spectral modification layer 315 can be used as an electrical rear contact for solar cells 310 and serve as an electrical conductor between solar cells 310.

In the illustrated embodiment, light (e.g., light 325) can be absorbed directly by solar cell 310 and/or scattered and Raman shifted by spectral modification layer 315. Raman shifted and/or scattered light (e.g., light 330) can be emitted from spectral modification layer 315 for absorption by solar cell 310. Spectral modification layer 315 can be made conductive to aid collection from multiple solar or photovoltaic cells.

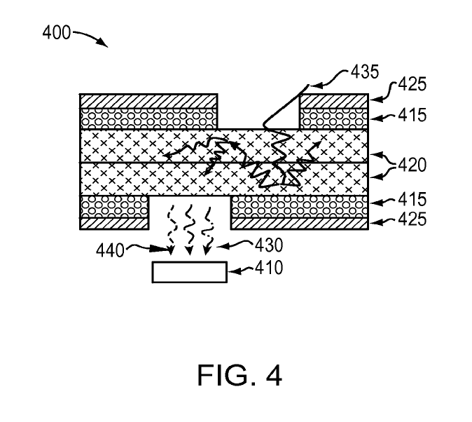

FIG. 4 depicts a cross-sectional view of a structure or device 400 that includes a solar cell 410 and spectral modification layers 415. Spectral modification layers 415 are in optical communication with transparent regions 420. Spectral modification layers 415 are also in optical communication with reflective layers 425. Solar cell 410 is separated from spectral modification layers 415, transparent regions 420, and reflective layers 425 by optical cavity 430. In the illustrated embodiment, light 435 can enter transparent regions 420 through an opening in spectral modification layers 415 and can be scattered by and Raman shifted by spectral modification layers 415 to produce scattered and Raman shifted light 440. Light 440 can be absorbed by solar cell 410. Transparent regions 420 can include glass, air, transparent plastic, etc. In some embodiments, structure or device 400 can be prepared by depositing spectral modification layers 415 onto two transparent regions 420 which are then stacked as shown.

Performance of the described structures and/or devices can be improved by controlling the temperature of the structures or devices (or portions thereof). For example, solar cells and Raman scattering materials can have different ideal temperatures of operation for maximum solar cell performance and Raman shifting. To address this, in some applications, structure or device 300 and optical cavity 320 of FIG. 3 can be maintained at a different temperature than solar cell 310.

The functionality of spectral modification layers (e.g., spectral modification layer 110 of FIG. 1 or spectral modification layer 210 of FIG. 2) can be improved (e.g., by greater scattering, Raman shifting, or reflecting of light) by the inclusion of additional particles and/or additional layers applied to the above described devices and/or structures. For example, light scattering or Raman shifting composite particles can be used to form multifunction composite layers to facilitate spectral modification.

Light scattering and/or Raman shifting layers applied to either the front face (illuminated) and/or back (non-illuminated) face of a solar cell and/or in optical communication with a solar cell can be made more efficient by the inclusion of additional particles and/or by additional layers applied to the described light scattering or Raman shifting particles. For example, composite particles can be constructed from Raman shifting materials, light scattering materials, dopant materials, conductive materials, and/or reflective materials, or any combination thereof. A multifunction, composite spectral modification layer can be formed from composite particles and/or multiple particle types.

Distinct layer(s) and/or materials may be applied to all or part of the particle surface to create multifunction particles. The deposition of materials onto a particle can combine the various elements of the described spectral modification layers (e.g., Raman shifting materials, light scattering materials, dopant materials, conductive materials, and/or reflective materials) into a composite particle. Composite particles can have a size ranging from approximately a nanometer to microns for preferable diffuse reflection of light and Raman shift spectral modification rates.

Some embodiments of composite particles include a Raman shifting material (e.g., diamond or silicone), a scattering material (e.g., TiO₂), and a reflective material (e.g., silver, aluminum alloys, or other reflective materials), or any combination thereof. For example, a composite particle can include diamond, TiO₂ and silver. A composite particle can include diamond and TiO₂. A composite particle can include diamond and silver. A composite particle can include TiO2 and silver.

Components of the described spectral modification layers can be in film form rather than particle form. Composite particles can be formed by coating particles with other materials. For example, metal can be coated onto Raman-scattering particles to form a more electrically conductive particle element. In some embodiments, a composite particle can be formed from a TiO₂ particle partially coated with silver; a TiO₂ particle partially coated with diamond and/or diamond-like film; or a TiO₂ particle partially or fully coated with diamond and partially coated with silver. In some embodiments, a composite particle can be formed from a silver particle partially or fully coated with diamond and/or diamond-like film; a silver particle partially or fully coated with TiO₂; or a silver particle partially or fully coated with diamond and/or diamond-like film and partially or fully coated with TiO₂. In some embodiments, dopant materials can be added to the composite particles. Existing coating technologies such as sputtering coating may be used to prepare these films and/or particles.

In some embodiments, composite particles consist of a low cost, non-light absorbing and/or light scattering particle (e.g., TiO₂) at least partially coated with diamond film. The particles can be at least partially coated with a reflective metal (e.g., aluminum) that is designed (e.g., by alloying and/or by thickness) to melt or partially melt at a temperature that will bond the particles and other materials together (e.g., at 850 C). The reflective material can, or other materials (e.g., boron) can be alloyed with the reflective metal to, have the capacity to dope (e.g., make more conductive) the near surface region of the solar cell material. For example, aluminum can be used as a dopant for silicon solar sales.

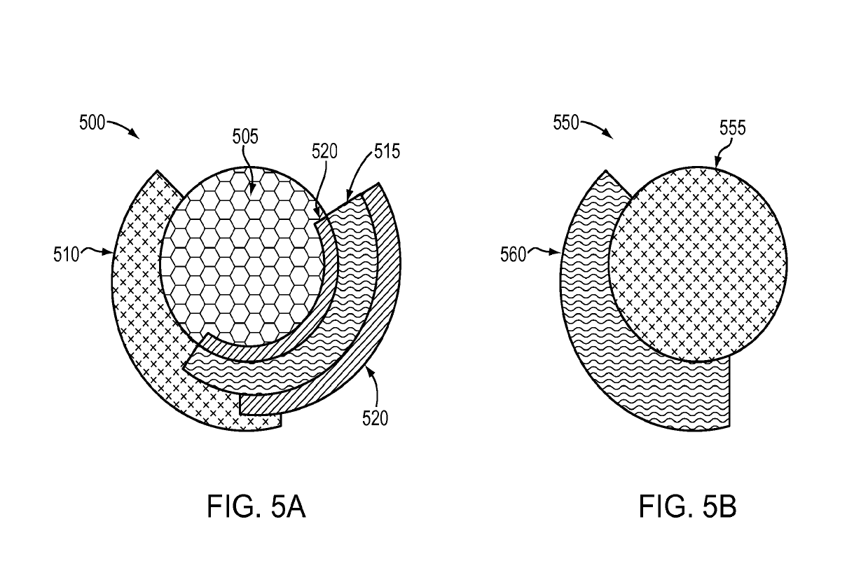

FIG. 5A depicts a composite particle 500. As illustrated, composite particle 500 includes a light scattering particle 505 (e.g., a TiO₂, glass, or plastic particle) partially coated with a Raman-shifting material film 510 (e.g., diamond, diamond powder, or any other strongly Raman-shifting material), and partially coated with a reflective film 515 (e.g., a metallic film, aluminum, etc.). The reflective film 515 can aid electrical conduction and may also serve as a semiconductor dopant source. In some embodiments, a reflection enhancing coating 520 can be applied to reflective film 515.

Composite Particle 500 can be used, for example, with and/or within any of the devices, structures, for films described herein. For example, composite particle 500 can be used in spectral modification layer 110 of FIG. 1 (e.g., as one or more of the Raman shifting particles 120, adhesion/cohesion material 125, reflective particles 130, or dopant material 135) or in spectral modification layer 210 of FIG. 2 (e.g., as one or more of the Raman shifting particles 220, adhesion/cohesion material 225, reflective particles 230, or dopant material 235).

FIG. 5B depicts a composite particle 550. As illustrated, composite particle 550 includes a metal particle coated with shifting material film 555 (e.g., diamond, diamond powder, or any other strongly Raman-shifting material). In some embodiments, particle 550 can be partially coated with a reflective film 560 (e.g., a metallic film, aluminum, etc.).

Composite particle 550 can be used, for example, with and/or within any of the devices, structures, for films described herein. For example, particle 550 can be used in spectral modification layer 110 of FIG. 1 (e.g., as one or more of the Raman shifting particles 120, adhesion/cohesion material 125, reflective particles 130, or dopant material 135) or in spectral modification layer 210 of FIG. 2 (e.g., as one or more of the Raman shifting particles 220, adhesion/cohesion material 225, reflective particles 230, or dopant material 235). As noted above, composite particles can be incorporated into and/or applied to any of the spectral modification layers described herein.

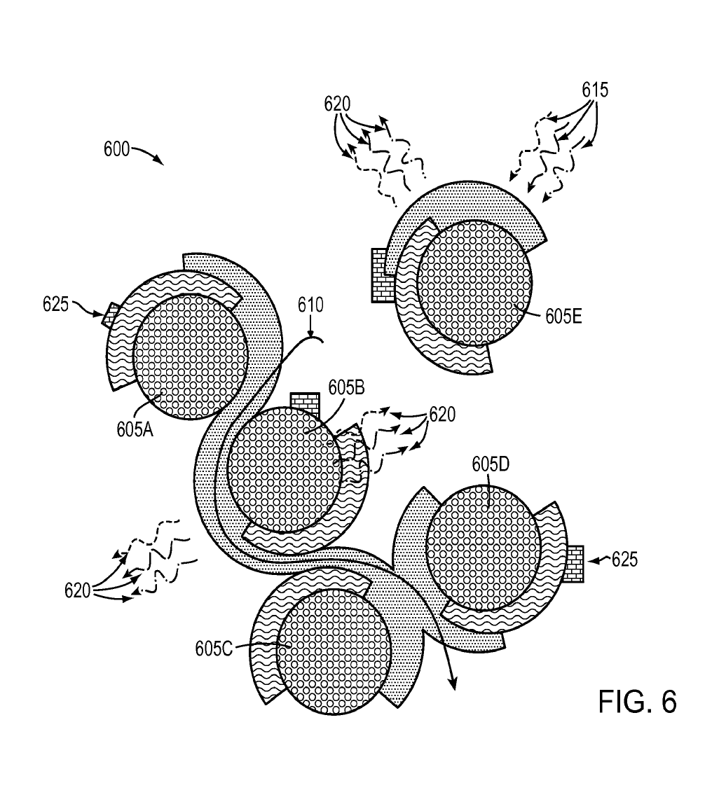

FIG. 6 depicts an arrangement 600 of composite particles 605A-605E. Composite particles 605A-605E can be, for example, one or more of composite particle 500, as shown in FIG. 5A. Composite particles 605A-605D are illustrated in an arrangement that can facilitate conduction of electricity. In the illustrated embodiment, particles 605A-605D form a conductive path 610. Conductive path 610 can be formed, for example, by the reflective film 515 of composite particle 500 shown in FIG. 5A.

Arrangement 600 can also facilitate spectral modification. For example, light 615 can be scattered and Raman-shifted by composite particles 605A-605E and emitted as light 620.

In some embodiments, a semiconductor dopant material 625 can be deposited onto composite particles 605A-605E.

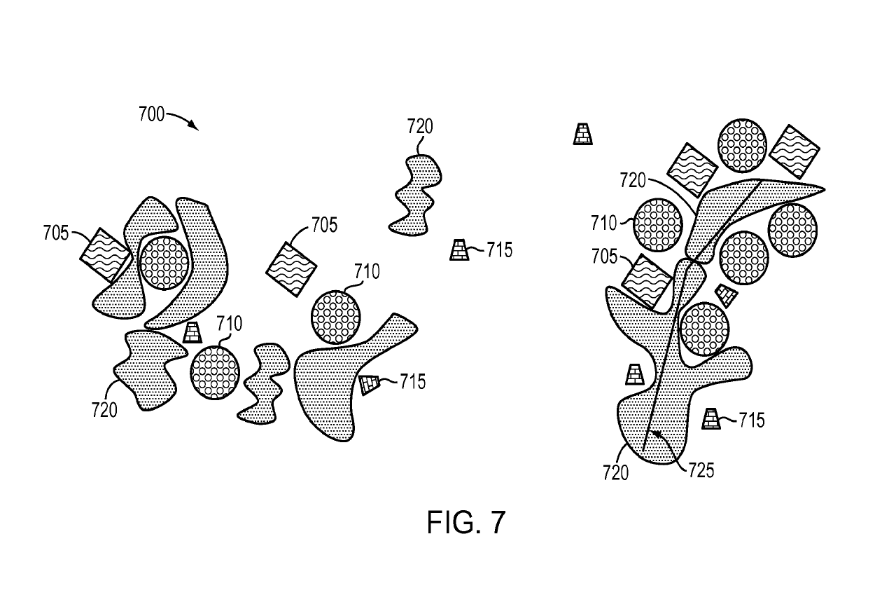

FIG. 7 depicts a composite spectral modification layer 700. Spectral modification layer 700 can include Raman shifting particles 705, scattering particles 710, dopant material 715, and reflective adhesion/cohesion material 720. During fabrication, spectral modification layer 700 can be heated to melt and fuse reflective adhesion/cohesion material 720 to form paths of improved electrical conductivity (e.g., path 725) without substantially blocking light traveling within and/or through spectral modification layer 700.

Spectral modification layer 700 can be used, for example, with and/or within any of the devices, structures, or films described herein. For example, spectral modification layer 700 can be used as the spectral modification layer for any of the embodiments described herein.

### Spectral Modification Layer Preparation

In some embodiments, the technology can involve films including Raman shifting particles. The Raman shifting particles can be silicon and/or diamond particles. The Raman shifting particles can be 2 nm in diameter or greater. In some applications, the Raman shifting particles can be approximately 50 nm in diameter. In some embodiments, the Raman shifting particles can be fully or partially coated with titanium oxide (TiO₂) or other transparent and/or anti-reflective coating to reduce reflection by the Raman shifting particles, thereby promoting more Raman shifting within the film. In some embodiments, the Raman-shifting particles can be metal, silver, titanium oxide, glass, or other material coated with a Raman shifting material (e.g., diamond or silicon).

In some embodiments, the Raman shifting and other particles can be embedded in a matrix. The matrix can include a transparent or semi-transparent material, such as a matrix including glass particles. In some applications, the Raman shifting particles can be embedded in a light scattering matrix of particles to form a film. The matrix can include TiO₂ particles. The film can include reflective particles, such as silver or aluminum. In some embodiments, the matrix can include particles of 2 nm in diameter or greater. In some applications, the matrix can include particles approximately 25-50 nm in diameter.

The film can be applied to glass substrates or applied to the front or back of commercially-available silicon solar cells. In applications where the film is applied to the back of the solar cell, the rear contact of the cell can be removed. The films can be applied to the solar cell by preparing a slurry of the Raman shifting particles and light scattering matrix particles in a solution of water, acetic acid, and isopropanol, and spraying the slurry onto glass substrate or a solar cell. The films can be dried (e.g., annealed) at approximately 500 Celsius for approximately 30 minutes and slowly cooled.

### Experimental Results

Raman shifting can involve both an up conversion and a down conversion probability on each interaction with photons. The Raman process can be viewed as a diffusion process in photon energy as well as a spatial diffusion process, where the spatial diffusion process involves the physical travel and path length of a photon scattering within the particle materials of, for example, the films described herein.

The films described herein can facilitate long travel paths of incident radiation (e.g., light) within the films and solar cells. Applying diffusion theory to the root-mean-square (rms) displacement, dᵣₘₛ, traveled by light yields Equation 1:

dᵣₘₛ²=Nl² (1)

In Equation 1, N is the number of path-altering scattering events and l is the distance between scattering events. Since the total travel light path displacement is given by d=Nl, d can in turn can be defined in terms of dᵣₘₛ as shown in Equation 2:

$$d = Nl = \frac{{Nl}^{2}}{l} = \frac{{d}_{rm s}^{2}}{l} \qquad ( 2 )$$

Approximately kilometer-length travel paths for radiation can be attained in media having nano-spaced scattering structures (e.g., TiO₂ particles) and where dᵣₘₛ is a few centimeters.

Experimental testing shows that the quantum efficiency at 1100 nm of the as-received commercial solar cells is in the range of approximately 10%. The value of 1100 nm is just beyond the band edge of the silicon solar cells used. The quantum efficiency of a solar cell using an aluminum-based rear contact can increase the quantum efficiency to approximately 15%. The 1100 nm quantum efficiency of solar cells in series with TiO₂-silver diffuse rear reflector can increase to approximately 30% despite the increased resistance from being connected in series (series resistance can only decrease the performance below what it would be without this parasitic loss).

Titanium oxide and diamond/titanium oxide mixed-particle films of various thicknesses were prepared and applied to the rear of commercial silicon solar cells (after removal of the as-delivered rear contact paste). Similar films were also deposited onto glass slides using a standard hobby spray apparatus. To facilitate film spraying, nanoparticles were mixed with isopropanol and water. The films were then annealed at 500° C. for one hour and slow-cooled. Film-coated glass slides were placed in front of the reference silicon solar cell (approximately 16% efficient under AM 1.5 illumination) and the quantum efficiency measured using a Newport Oriel quantum efficiency system with and without bias light. These same films were also placed in front of a standard germanium reference photovoltaic cell for visible and infrared (“IR”) spectral transmission measurement. An approximately 1.5 watt CW visible light laser was used for the bias light cases. These experiments were also performed with Titanium oxide and zirconium oxide/titanium oxide mixed-particle films.

The Raman spectra of various embodiments of the technology (e.g., films) were measured. The Raman shifting of 785 nm wavelength light by silicon and diamond nano-particles (e.g., particles approximately 50 nm in diameter) was measured and compared to Raman shifting in bulk crystals of the same materials. To quantify Raman shifting spectrum modification or management, glass substrates coated with the films described herein were placed in front of a reference silicon solar cell (the solar cell having approximately 16% efficiency under AM 1.5 illumination) and the quantum efficiencies were measured. Measurements were made with and without bias light. For comparison to a flatter spectral response photovoltaic cell and for long wavelength measurement a commercial germanium photovoltaic cell was also used.

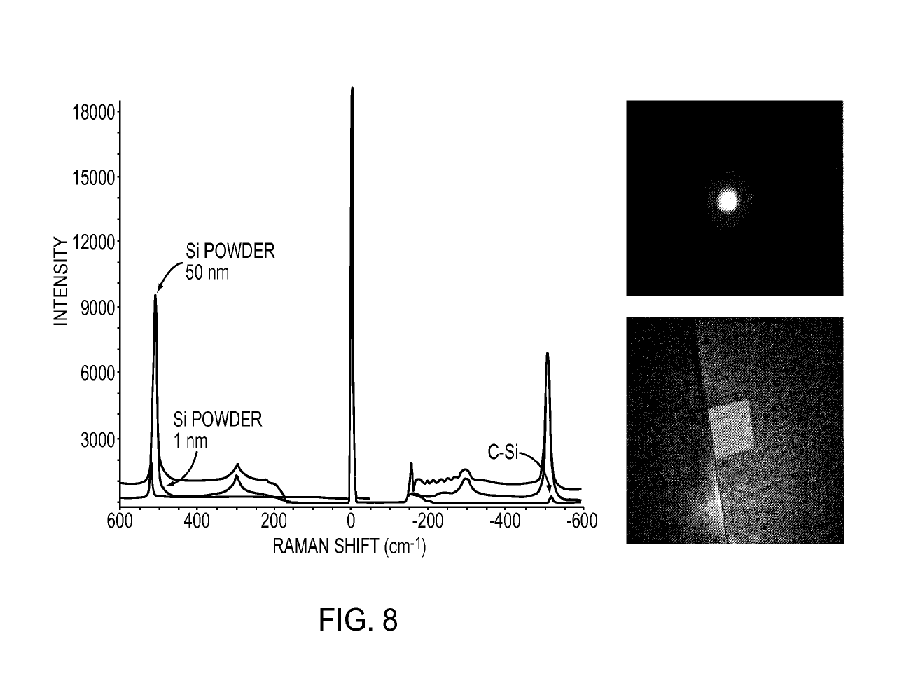

The Raman shifts of bulk crystal and nanoscale (e.g., approximately 1 μm) crystalline particles systems known to have large Raman shifts were measured using a Thermo Nicolet Almega dispersive Raman Spectrometer. FIG. 8 depicts the Raman spectra of crystalline and nanoscaled particle silicon as a function of light intensity. In FIG. 8, the response of silicon nanoparticles (e.g., 100 nm range) is shown. It was found that the Raman shift to the Anti-Stokes-to-Stokes ratio of the particle systems were greater than their bulk crystal counterparts. A relatively large Raman shift for particles, as compared with bulk crystal, was also found in visible-light-transparent particle systems. In all cases the Anti-Stokes-to-Stokes ratio increased with increasing probe and with bias light.

FIG. 8 is a graph showing the Raman spectra of bulk single crystal silicon compared to the Raman spectra of nano-scaled particle silicon. As seen in the inset of FIG. 8, the dᵣₘₛ of a TiO₂ film on a glass substrate is approximately 1 cm. Taking the scattering distance to be 25 nm, the TiO₂ particle diameter, yields a light path length of approximately 4 km.

As noted, the technology can utilize films including Raman shifting particles (e.g., silicon or diamond particles) in a matrix (e.g., TiO₂ particles). In some embodiments, the Raman shifting particles and matrix are approximately transparent so as not to absorb light as it Raman and spatially scatters.

To test the ability of TiO₂ particle matrices to spatially scatter light with little absorption, TiO₂ films were applied in place of rear contacts on commercially-available silicon solar cells. The travel paths of light within the TiO₂ films can increase the probability of the light being absorbed within the solar cell. The travel paths of light within the TiO₂ films can also increase the probability of Raman shifting events within the films because as light is scattered within these films, the light can encounter the Raman shifting particles multiple times.

A consideration for embodiments of the technology is the ratio of Raman shifting resulting in up-energy shifts, or anti-Stokes shifts, resulting in shorter wavelength light to Raman shifting resulting in down-energy shifts, Stokes shifts, resulting in shorter wavelength light. The down-energy shift probability is governed by phonon emission probabilities (or optical coupling constant) while the up-energy shift probability is governed by both the phonon absorption probability and the densities of pre-existing phonons.

FIG. 8 illustrates that the ratio of Stokes to anti-Stokes shift events in silicon is a product of silicon crystal particle size, with the net Raman shift as well as the anti-Stokes shift to Stokes ratio increasing with decreasing particle size. Embodiments of the technology including diamond particles can behave in a similar manner. The anti-Stokes shift probability in both diamond and silicon particles can increase with increasing probe beam intensity and/or bias light.

For example, when the Raman spectra of diamond nano-particles were compared to bulk diamond crystal using a 785 nm wavelength probe beam, the anti-Stokes to Stokes ratio was 0.012 for bulk diamond crystal and was 0.343 for diamond nano-particles. Accordingly, experimental results indicate that diamond nano-particles have a greater anti-Stokes response relative to the Stokes response than bulk diamond crystal. When decreasing the probe beam intensity, the anti-Stokes to Stokes ratio decreased to 0.062 for diamond nano-particles whereas there was no significant change in the bulk diamond crystal case.

Experimental results showed the net Raman shift and the anti-Stokes to Stokes ratio increased with decreasing particle size and with increasing probe beam intensity (and bias light) for both diamond and silicon, suggesting that the increased anti-stokes response is not due to particle heating. The experimental results are consistent with a phonon transfer mechanism in which phonons generated by Stokes shift events contribute to the phonon density in the exact wavelength ranges needed for subsequent anti-Stokes events. Long phonon lifetime is expected in small particles since phonon decay, in part, relies upon longer wavelength phonon decay products (Umklapp processes) that cannot exist in small-sized particles.

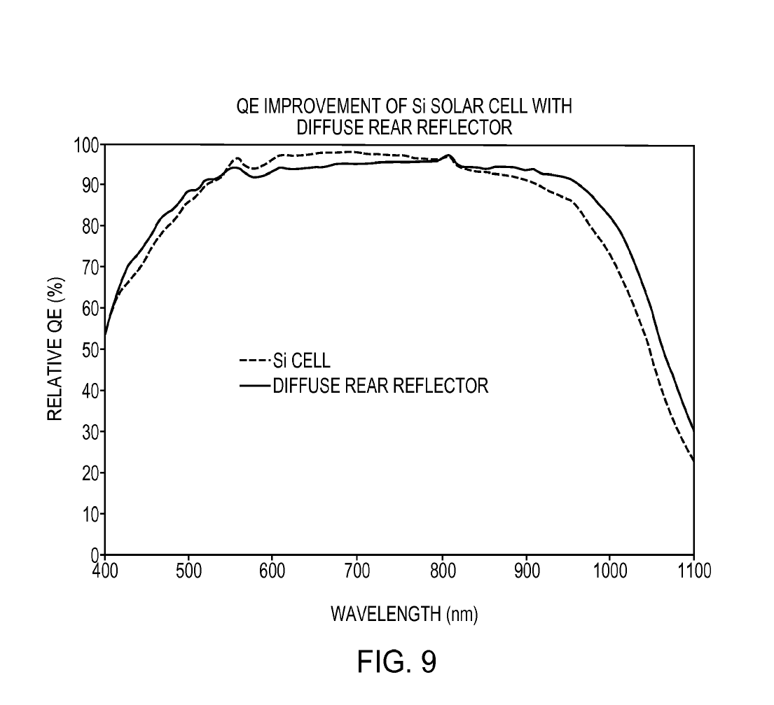

FIG. 9 depicts a comparison of a commercial solar cell with the as-delivered rear contact to a solar cell with a diffuse titanium oxide-based rear reflector. As shown in FIG. 9, a titanium oxide diffuse rear reflector can increase the quantum efficiency at, for example, wavelengths (λ) of approximately 1,100 nm by up to approximately 25% as compared to the aluminum pastes typically used on commercial crystal silicon solar cells. These rear scattering layers enable the use of flat, minimal-area, front contacts that can decrease the front surface recombination by more than a factor of two, when compared with a triangular light-scattering front surface structure.

The Raman shifts of the particle systems can produce both the larger amplitude shifts as well as the larger Anti-Stokes-to-Stokes ratios when compared to the bulk crystal of the same materials. The Anti-Stokes-to-Stokes shift increased with increasing probe beam intensity and it also increased with bias light illumination. The results are consistent with a phonon transfer mechanism, in which a phonon generated by a Stokes shift event leaves behind a long-enough-lived phonon to contribute to an anti-Stokes shift (energy-increasing) event. Careful analysis based upon a diffusion in energy predicted that more than approximately 30% of the Raman-shifted light will be towards higher energies where the photon could contribute to power generation.

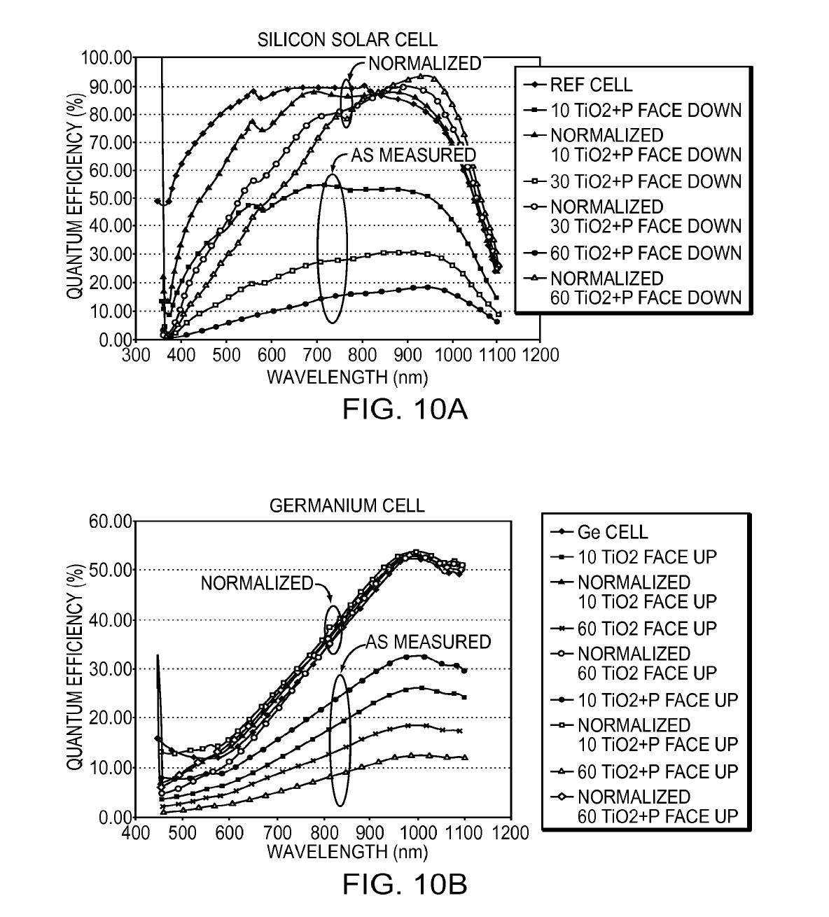

Various films comprised of titanium oxide particles or titanium particles, which can facilitate Raman shifting, on glass substrates were placed in front of a standard silicon reference cell. FIG. 10 depicts the quantum efficiency of standard solar cells. FIG. 10 illustrates that the back-scattering of the light reduced the overall quantum efficiency of the solar cell as film thickness increased. When the same films were placed in front of the germanium solar cells, the relatively featureless response of the germanium photovoltaic cell reveals a spectrally flat decrease in solar cell quantum efficiency, indicating no spectral bias in either film transmission or film light scattering.

Light transmission of the various films are spectrally flat—the quantum efficiency (“QE”) curves were normalized with respect to the response without film cover. The resultant plot is also shown in FIG. 10. FIG. 10 shows that, with strong Raman-scattering particles and with light bias, there is a distinct increase in the quantum efficiency (“QE”) near the band edge of silicon of 1100 nm.

Graph A of FIG. 10 shows the spectra response of a silicon solar cell with various diamond particle-based films on glass substrates placed on the front (light incident side) of the cell. The films of TiO₂ and diamond particles on glass substrate were placed in front of a silicon solar cell to measure the quantum efficiency gains resulting from Raman shift-based spectral modification or management provided by the films. The films reduced the overall quantum efficiency of both cells with increasing film thickness due to the amount of light back-scattered away from the solar cell. The quantum efficiencies shown in FIG. 10 were normalized (as indicated) with respect to the response without the particle films. The experimental results show that when used with films containing diamond nano-particles, the silicon solar cell has increased quantum efficiency near the band edge of silicon and a relative lack of response for the germanium phovoltaic cell (Graph B of FIG. 10).

Where the band-edge light makes many passes through the solar cell and is returned and re-scattered by the particles within the film, the Raman shift probability can be increased. The resulting anti-Stokes shifting of near band edge light contributes to the observed quantum efficiency for 975 nm wavelength light, as shown in Graph A of FIG. 10. The lack of similar gains in the germanium solar cell cases is consistent with all light in the measured spectral region being absorbed on its first pass through the solar cell.

Spectral broadening can be quantified by considering an approximate random walk (e.g., approximate because up and down Raman shifts can have different probabilities in particle systems) in energy where the diffusion coefficient (D) for energy hopping for Raman shifting in silicon is provided by Equation 3:

$$D = \frac{1}{2} {Γ ( Δ {E}_{shift} )}^{2} = \frac{1}{2} ( β \frac{c}{N} ) {( Δ {E}_{shift} )}^{2} = \frac{1}{2} ( β \frac{c}{N} ) {( 0.06 )}^{2} \qquad ( 3 )$$

In Equation 3, c is the speed of light, N is the refractive index, β is the Raman shifting probability per unit length, and 0.06 eV is the energy per Raman shift in silicon particles (the energy per Raman shift in diamond is larger).

Diffuse rear reflectors offer the advantage of scattering light to sufficiently large angles so as to increase probability of total internal reflection at the front surface and, therefore, much longer light path lengths within the solar cell absorber layer, when compared to a simple mirror-like rear reflector. To obtain a relatively large scattering angle within a high index solar cell (e.g., the refractive index of silicon is greater than 3.4), the diffuse rear reflector should also have a large refractive index. For example, a sintered rear reflector has been found capable of increasing the long wavelength response by approximately 25%. Interestingly, while diffuse rear reflectors increase performance, diffuse front reflectors decrease performance by approximately greater than 40%, mostly due to the large amount of light scattered and/or reflected out of the front of the solar cell (see, e.g., FIG. 10).

The diffusion equation of energy hopping derived from that in semiconductors is Equation 4:

$$D \frac{{d}^{2} n}{d {E}^{2}} - α \frac{c}{N} n + G = 0 , \\ \text{?} = 0 , {n}_{0} = 0 \\ \text{?} \text{indicates text missing or illegible when filed} \qquad ( 4 )$$

In Equation 4, G is the incident flux of photon and a is the absorption coefficient. The lifetime of a photon is considered as a function of the absorption because the photon is assumed to live until it is absorbed. The boundary conditions are that no photon is scattered to zero energy and all photons with energy higher than the band gap are absorbed. The solution of Equation 4 is Equation 5:

$$n ( E ) = ( - G \frac{d}{v} ) [ \frac{1 - {e}^{( - \sqrt{\frac{v}{\text{?}}} \text{?} )}}{{e}^{( \sqrt{\frac{v}{Dd}} \text{?} )} - {e}^{( - \sqrt{\frac{v}{Dd}} \text{?} )}} ] {e}^{( \sqrt{\frac{v}{Dd }} E )} + ( G \frac{d}{v} ) [ \frac{1 - {e}^{( \sqrt{\frac{v}{Dd}} \text{?} )}}{{e}^{( \sqrt{\frac{v}{Dd}} \text{?} )} - {e}^{( - \sqrt{\frac{v}{Dd}} \text{?} )}} ] {e}^{( - \sqrt{\frac{v}{Dd}} E )} + G \frac{d}{v} \\ \text{?} \text{indicates text missing or illegible when filed} \qquad ( 5 )$$

The collected photon current (e.g., photons having achieved an energy sufficient for absorption within the solar cell) is given by Equation 6:

$$J = D ∇ \text{?} = ( - G \sqrt{\frac{Dd}{v}} ) [ \frac{{e}^{( \sqrt{\frac{v}{Dd}} \text{?} )} + {e}^{( - \sqrt{\frac{v}{Dd}} \text{?} )} - 2}{{e}^{( \sqrt{\frac{v}{Dd}} \text{?} )} - {e}^{( - \sqrt{\frac{v}{Dd}} \text{?} )}} ] = - G \sqrt{\frac{Dd}{v}} [ coth ( \sqrt{\frac{v}{Dd}} \text{?} ) - csch ( \sqrt{\frac{v}{Dd}} \text{?} ) ] \\ \text{?} \text{indicates text missing or illegible when filed} \qquad ( 6 )$$

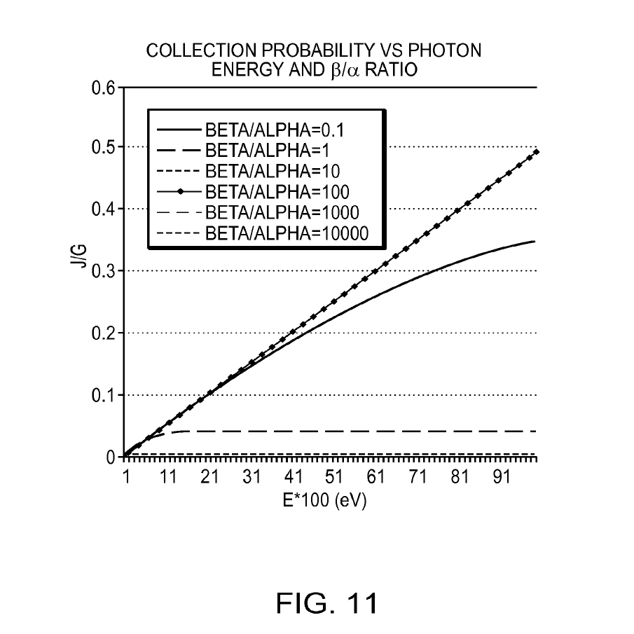

FIG. 11 is a graph showing the ratio of collected photon current to the incident photon flux as a function of the photon energy based on Raman-induced energy diffusion of light. FIG. 11 illustrates that the probability of Raman shifting must be larger than the probability of absorption. This is consistent with the result of FIG. 10, where the increase in response is seen in the near-band-edge region of silicon where absorption is low and the energy-distance to collection is small because as the ratio of Raman shifting to absorption probability decreases, the ability to collect low energy photon decreases.

What is claimed is:

1. An apparatus for spectral modification of incident radiation comprising:
a substrate; and
Raman shifting material on or embedded in the substrate, the Raman shifting material selected based on a desired optical or electrical performance of a light absorbing structure.

2. The apparatus of claim 1, wherein the Raman shifting material comprises nano-scale particles and powdered materials.

3. The apparatus of claim 2, wherein the powdered materials comprise diamond powder.

4. The apparatus of claim 2, wherein the nano-scale particles comprise silver, aluminum, aluminum alloy, or any combination thereof.

5. The apparatus of claim 1, wherein the Raman shifting material comprises titanium oxide, diamond, or any combination thereof.

6. The apparatus of claim 1, further comprising reflective material embedded in or on the substrate.

7. The apparatus of claim 1, further comprising silicon dopants embedded in or on the substrate.

8. The apparatus of claim 1, wherein the Raman shifting material comprises one or more composite particles, each composite particle comprising:
a first particle, wherein the first particle comprises one of scattering material, Raman shifting material, or reflective material; and
a first material disposed against at least a portion of the first particle, wherein the first material comprises one of scattering material, Raman shifting material, or reflective material, further wherein the first particle and the first material comprise different materials.

9. An apparatus comprising:
a solar cell;
a spectral modification layer disposed against at least a portion of the solar cell, the spectral modification layer comprising a Raman shifting material selected based on a desired optical or electrical performance of the solar cell.

10. The apparatus of claim 9, wherein the Raman shifting material comprises nano-scale particles and powdered materials.

11. The apparatus of claim 10, wherein the powdered materials comprise diamond powder.

12. The apparatus of claim 10, wherein the nano-scale particles comprise silver, aluminum, aluminum alloy, or any combination thereof.

13. The apparatus of claim 9, wherein the Raman shifting material comprises titanium oxide, diamond, or any combination thereof.

14. The apparatus of claim 9, further comprising reflective material embedded in or on the substrate.

15. The apparatus of claim 9, further comprising silicon dopants embedded in or on the substrate.

16. The apparatus of claim 9, wherein the solar cell is a silicon solar cell or dye-type solar cell.

17. The apparatus of claim 9, wherein the Raman shifting material comprises one or more composite particles, each composite particle comprising:
a first particle, wherein the first particle comprises one of scattering material, Raman shifting material, or reflective material; and
a first material disposed against at least a portion of the first particle, wherein the first material comprises one of scattering material, Raman shifting material, or reflective material, further wherein the first particle and the first material comprise different materials.

18. A method of manufacturing a spectral modification material comprising:
forming a substrate; and
embedding in or disposing on the substrate a Raman shifting material, the Raman shifting material selected based on a desired optical or electrical performance of a light absorbing structure.

19. A method of reducing series resistance of a solar cell comprising:
selecting a Raman shifting material based on a desired optical performance of the solar cell;
selecting a conductive material based on a desired electrical performance of the solar cell, wherein the conductive material is at least partially reflective; and
disposing a spectral modification layer in optical communication with a portion of the solar cell, the spectral modification layer comprising the Raman shifting material and the conductive material.

20. A method of reducing series resistance between two or more solar cells comprising:
selecting a Raman shifting material based on a desired optical performance of the two or more solar cells;
selecting a conductive material based on a desired electrical performance of the two or more solar cells, wherein the conductive material is at least partially reflective; and
disposing a spectral modification layer in optical and electrical communication with a portion of each of the two or more solar cells, the spectral modification layer comprising the Raman shifting material and the conductive material.

21. A composite particle comprising:
a first particle, wherein the first particle comprises one of scattering material, Raman shifting material, or reflective material; and
a first material disposed against at least a portion of the first particle, wherein the first material comprises one of scattering material, Raman shifting material, or reflective material, further wherein the first particle and the first material comprise different materials.

22. The composite particle of claim 21 further comprising:
a second material disposed against at least a portion of the first particle, wherein the second material comprises one of scattering material, Raman shifting material, or reflective material, further wherein the first particle, the first material, and the second material comprise different materials.

23. The composite particle of claim 21, wherein the Raman shifting material comprises diamond.

24. The composite particle of claim 21, wherein the scattering material comprises titanium oxide.

25. The composite particle of claim 21, wherein the reflective material comprises silver, aluminum, aluminum alloy, or any combination thereof.

26. The composite particle of claim 21 further comprising dopant material disposed against the first particle.
